(19) United States
(12) Patent Application Publication
(10) Pub. No.: US 2001/0035573 A1
(43) Pub. Date: Nov. 1, 2001

(54) Mounting platform with light passage opening for an optical transmission and receptions unit

(76) Inventor: Martin Weigert, Hardt (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/767,381

(22) Filed: Jan. 22, 2001

(30) Foreign Application Priority Data
Jan. 20, 2000 (DE) 100 02 328.2

(51) Int. Cl. H01L 23/04; H01L 23/02

(52) U.S. Cl. 257/680; 257/678

(57) ABSTRACT

A mounting platform for an optical transmission and/or reception unit contains at least one passage opening, on one side of the mounting platform a transmission or reception diode chip is fastened on a support plate in such a way that it immediately faces the passage opening. A reception diode chip may also be fastened directly on the mounting platform. An optical beam guiding device, such as a beam deviation receptacle, with a fiber connection for an optical fiber, may be fastened on a second main surface.

### BACKGROUND OF THE INVENTION

Field of the Invention

The invention relates to an optical transmission and/or reception unit, and this case to the fastening of a transmission and/or reception diode chip on a mounting platform that has passage openings. A transmission and/or reception unit according to the invention is, in particular, intended for use in the case of receptacle components, in which an optical device for beam guiding, in particular a beam deviation receptacle with a fiber connection opening, is mounted on the mounting platform.

Because of the high packing density that is desired in many optical applications, surface mounting technology is becoming particularly important in the field of optoelectronics. A large number of optoelectronic components are already known which are surface-mountably configured using a surface mounting technology (SMT) concept.

In the case of fiber optic transmission or reception components, one aim is to achieve the best possible optical coupling between an optical fiber and an optoelectronic transmitter or receiver, generally a semiconductor laser or a semiconductor photodiode. The surface-mountable fiber optic transmission or reception components known in the prior art have an surface mounted device (SMD) mounting frame, which contains connection pins that are linked via electrical feed-throughs to a transmitter or receiver, such as a semiconductor laser or a semiconductor photodiode, fitted in the mounting frame. A beam deviation device, which contains at least a lens, a deviating mirror and an at least axially displaceable guide tube, is mounted on the mounting frame. Inside the mounting frame there is a mounting platform which has feed-throughs, on one side of which the transmitter or receiver is fastened on a transparent silicon submount. The transmitter, for example an edge-emitting semiconductor laser, emits a laser radiation beam parallel with the plane of the mounting platform. The beam is deviated through an angle of 90° by a configuration of prismatic optical elements on the submount and passes through the transparent submount via the passage opening of the mounting platform. A beam deviation receptacle, fastened on the other side of the mounting platform, contains a deviating mirror which injects the laser radiation beam into an optical fiber which is fastened in a fiber connection opening. In a bi-directional application, a radiation beam extracted from the optical fiber is directed by the deviating mirror through the transparent submount onto a receiver diode.

In the devices known to date, it is therefore necessary to fabricate the submount for the transmission or reception diode chip from a transparent material. Glass or a suitable semi-insulating semiconductor material with a sufficiently large band gap is therefore used in general. The material selection for the submount is thereby restricted from the outset, with even selected transparent materials exhibiting residual absorption at the wavelength of interest, which entails a loss of light.

### SUMMARY OF THE INVENTION

It is accordingly an object of the invention to provide a mounting platform with light passage openings for an optical transmission and a reception unit which overcomes the above-mentioned disadvantages of the prior art devices of this general type, in which an optical transmission or reception diode chip is fastened in the most practical way possible on a mounting platform of the known type. In particular, the object of the present invention is to carry out the fastening in such a way that a support plate which is optionally to be used for the fastening, or a submount, is subjected to no particular restriction in terms of the material selection. With the foregoing and other objects in view there is provided, in accordance with the invention, an optical unit. The optical unit contains a mounting platform having a first main surface, a second main surface, and at least one passage S opening formed therein and extending between the first main surface and the second main surfaces. A support plate extends on a side of the first main surface and extends at least partially over the passage opening. A diode chip being at least one of a transmission and reception diode chip is disposed on the support plate and is fastened such that the diode chip immediately faces the passage opening.

The transmission and/or reception diode chip is therefore not separated from the passage opening by the support plate or the submount, so that these do not even have to be fabricated from a transparent material. It is instead possible to use any desired material for the support plates. The support plate may particularly advantageously be selected from a semiconductor material, such as silicon, so that it can be used not only as the support for a transmitter diode chip, but also at the same time as the light-reception surface of a reception diode, in particular of a monitor diode for the transmitter diode.

The transmission or reception diode chip may either be fastened directly on the support plate or may be fastened on a submount, which is in turn fastened on the support plate. In both cases, the support that holds the transmitter diode chip, i.e. in the former case the support plate or in the latter case the submount, may be produced from a semiconductor material, in particular silicon. In addition, a surface of the support plate or of the submount may be usable and configured as the light-reception surface of a reception diode, in particular of a monitor diode for the transmitter diode.

For the case in which a submount is used, the latter may also be fabricated from a semiconductor material without having an optoelectronic function at the same time, i.e. being used as a reception diode chip. The support plate may also—irrespective of whether it directly carries the transmission or reception diode chip or whether the latter is carried by the submount—be produced from any desired material, for example a semiconductor material or a ceramic material.

The mounting platform may be produced from a plastic material, and electrical interconnections for contacting of the transmission or reception diode chip is provided on the first main surface of the mounting platform. The mounting platform may alternatively be produced from a lead frame in a manner that is known per se.

The second embodiment has the advantage that it does not necessitate the use of the support plate or the submount for the reception diode chip, since the latter itself at least partially covers the passage opening and the reception light strikes the light-reception surface of the reception diode chip immediately after passing through the passage opening.

In the case of the second embodiment as well, the mounting platform may be produced from an electrically insulating material, such as a plastic material, with electrical interconnections for contacting of the reception diode chip being disposed on the first main surface, or it may be produced from a lead frame in a manner which is known per se. A preamplifier may in this case additionally be integrated in the reception diode chip.

In the case of both embodiments of the present invention, the optical transmission and/or reception unit may be developed to form an optical transmission and/or reception component by fastening the optical device for beam guiding on the second main surface of the mounting platform. This device may, for example, in a manner which is known per se, be formed by a beam deviation receptacle which has a deviating mirror and a connection opening for an optical fiber. The deviating mirror is in this case disposed above the passage opening and opposite the transmission or reception diode chip. The transmission beam is deviated by the deviating mirror at a 90° angle into a direction parallel with the plane of the mounting platform, and is injected into an attached optical fiber. Reciprocally, a reception beam emerges from the optical fiber and is deviated by the deviating mirror at a 90° angle through the passage opening onto a reception diode chip. A lens, such as a spherical lens or another converging lens, may furthermore be held in a suitable way inside the passage opening or between the deviating mirror and the fiber connection opening, or the deviating mirror may be configured as a focusing mirror.

The optical transmission and/or reception unit may also be developed to form a surface-mountable optical transmission and/or reception component by providing it with external electrical connections. The electrical connections are linked to corresponding connection sections of the mounting platform and are lead out in such a way that, in each case, they have end sections lying in a common plane. In addition, the optical transmission and/or reception unit and the electrical connections may be at least partially encapsulated by a plastic compound, from which the electrical connections are led out in the manner described. Inside the plastic encapsulation, the electrical connections may be linked by bonding wires to the interconnections of the mounting platform, or may be directly linked to the mounting platform produced from a lead frame.

In accordance with an added feature of the invention, the diode chip is fastened directly on the first main surface of the support plate.

In accordance with an additional feature of the invention, a submount is provided on which the diode chip is fastened, and the submount is fastened on the support plate.

In accordance with another feature of the invention, the submount is produced from a semiconductor material, in particular from silicon. The diode chip is a transmission diode chip fastened on the submount, and the submount is a photodiode.

In accordance with a further feature of the invention, the submount is produced from a semiconductor material, including silicon.

In accordance with another added feature of the invention, the support plate is produced from a ceramic material.

In accordance with another additional feature of the invention, electrical interconnections for electronic contacting of the diode chip are disposed on the first main surface of the mounting platform.

In accordance with a further added feature of the invention, the mounting platform is produced from a lead frame.

With the foregoing and other objects in view there is further provided, in accordance with the invention an optical unit. The optical unit contains a mounting platform having a first main surface, a second main surface, and at least one passage opening formed therein and extending between the first main surface and the second main surface; and a reception diode chip having a light-reception surface and extending on a side of the first main surface at least partially over the passage opening, so that the light-reception surface of the reception diode chip immediately faces the passage opening.

In accordance with an added feature of the invention, a preamplifier is integrated in the reception diode chip.

In accordance with an additional feature of the invention, electrical interconnections are disposed on the first main surface of the mounting platform and are connected to the reception diode chip.

With the foregoing and other objects in view there is provided, in accordance with the invention, an optical component. The optical component contains an optical unit, including a mounting platform having a first main surface, a second main surface, electrical interconnections disposed on the first main surface, and at least one passage opening formed therein and extending between the first main surface and the second main surfaces. A support plate extends on a side of the first main surface and extends at least partially over the passage opening. A diode chip being at least one of a transmission and reception diode chip is disposed on the support plate and is fastened such that the diode chip immediately faces the passage opening. Electrical connections are connected to the electrical interconnections of the mounting platform and the electrical connections are lead out in such a way that, in each case, the electrical connections have end sections lying in a common plane.

In accordance with an added feature of the invention, a plastic encapsulation at least partially surrounds the optical unit and the electrical connections, and the electrical connections extend out from the plastic encapsulation.

With the foregoing and other objects in view there is provided, in accordance with the invention, an optical component. The optical component contains an optical unit, containing a mounting platform having a first main surface, a second main surface, electrical interconnections disposed on the first main surface, and at least one passage opening formed therein and extending between the first main surface and the second main surfaces. A support plate extends on a side of the first main surface and extends at least partially over the passage opening. A diode chip being at least one of a transmission and reception diode chip is disposed on the support plate and is fastened such that the diode chip immediately faces the passage opening. An optical device for beam guiding is disposed on the second main surface of the mounting platform.

In accordance with another feature of the invention, the optical device is a beam deviation receptacle with a deviating mirror and a connection opening for an optical fiber.

In accordance with a further feature of the invention, the submount is a monitor diode for the transmitter diode chip.

With the foregoing and other objects in view there is provided, in accordance with the invention, an optical component. The optical component contains an optical unit, including a mounting platform having a first main surface, a second main surface, electrical interconnections disposed on the first main surface, and at least one passage opening formed therein and extending between the first main surface and the second main surface. A reception diode chip is provided and has a light-reception surface and extends on a side of the first main surface at least partially over the passage opening, so that the light-reception surface of the reception diode chip immediately faces the passage opening. Electrical connections are connected to the electrical interconnections of the mounting platform and the electrical connections being lead out in such a way that, in each case, the electrical connections have end sections lying in a common plane.

In accordance with another feature of the invention, a plastic encapsulation at least partially surrounds the optical unit and the electrical connections, and the electrical connections extend out from the plastic encapsulation.

With the foregoing and other objects in view there is provided, in accordance with the invention, an optical component. The optical component contains an optical unit, including a mounting platform having a first main surface, a second main surface, electrical interconnections disposed on the first main surface, and at least one passage opening formed therein and extending between the first main surface and the second main surface. A reception diode chip is provided and has a light-reception surface and extends on a side of the first main surface at least partially over the passage opening, so that the light-reception surface of the reception diode chip immediately faces the passage opening. An optical device for beam guiding is disposed on the second main surface of the mounting platform.

In accordance with a concomitant feature of the invention, the optical device is a beam deviation receptacle with a deviating mirror and a connection opening for an optical fiber.

Other features which are considered as characteristic for the invention are set forth in the appended claims.

Although the invention is illustrated and described herein as embodied in a mounting platform with light passage openings for an optical transmission and a reception unit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, longitudinal sectional view along a passage opening of a first illustrative embodiment of an optical transmission and/or reception unit according to the invention;

FIG. 2 is a longitudinal sectional view of a second illustrative embodiment of the optical transmission and/or reception unit;

FIG. 3 is a longitudinal sectional view of a third illustrative embodiment of the optical transmission and/or reception unit, with a transmission and/or reception diode chip;

FIG. 4 is a longitudinal sectional view of a development of the second illustrative embodiment of the optical transmission and/or reception unit, represented in FIG. 2, to form a surface-mountable component; and

FIG. 5 is a perspective view of a surface-mountable component.

### DESCRIPTION OF THE PREFERRED EMBODIMENTS

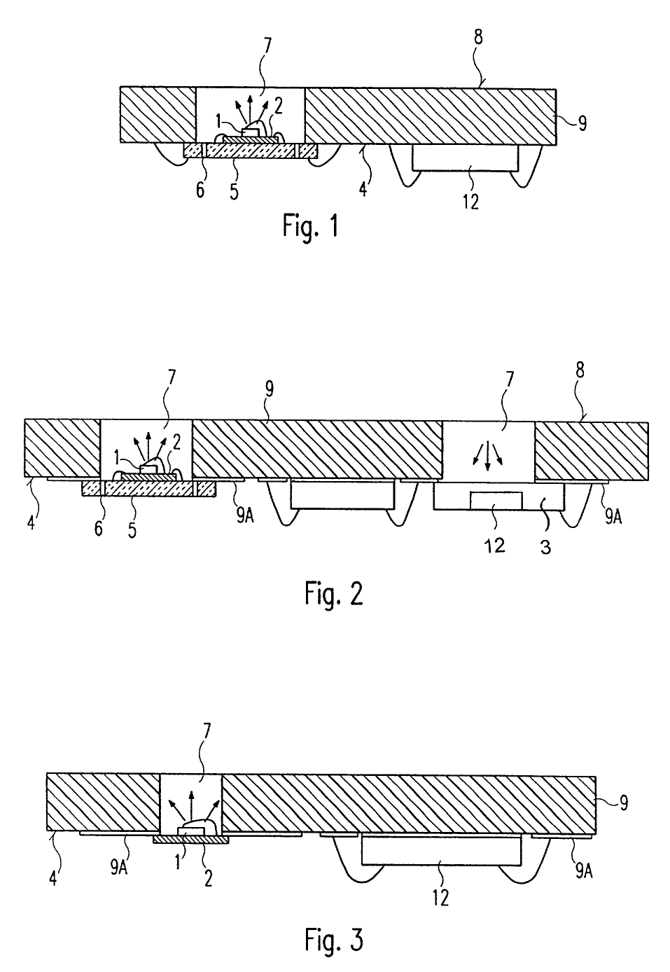

In all the figures of the drawing, sub-features and integral parts that correspond to one another bear the same reference symbol in each case. Referring now to the figures of the drawing in detail and first, particularly, to FIG. 1 thereof, there is shown a mounting platform 9 that is produced in a manner which is known per se from a lead frame. In the final state, the mounting platform 9 therefore contains conductive connection sections, which at first are still in the form of a coherent structure but, in the course of the production process, are separated by cutting junction bridges between them. The mounting platform 9 has a first main surface 4 and a second main surface 8, between which a generally circular passage opening 7 extends through the mounting platform 9. FIGS. 1 to 4 in each case represent longitudinal sections along a mid-plane axes of such circular passage openings 7.

The first main surface 4 of the mounting platform 9 is used for fastening an optical transmission or reception diode chip 1. The transmission diode chip 1 is mounted in such a way that the radiation beam emitted by it passes through the passage opening 7, while the reception diode chip 1 is mounted in such a way that the radiation beam incident through the passage opening 7 strikes its photosensitive reception surface.

An optical beam guiding device, such as a so-called beam deviation receptacle (not shown), which has a fiber connection opening for an optical guide fiber and by which optical coupling of the transmission or reception diode chip 1 to the optical fiber is produced, may be mounted on the second main surface 8 of the mounting platform 9. A beam deviation receptacle generally has an integrated deviating mirror, which is disposed at a 45° angle with respect to the second main surface 8 above the passage opening 7, i.e. opposite the transmission or reception diode chip 1.

A radiation beam emitted by the transmission diode chip 1 is therefore injected by the deviating mirror into an optical fiber fitted into the beam deviation receptacle, while a radiation beam emerging from such an optical fiber is directed by the deviating mirror onto the reception diode chip 1. A lens, such as a spherical lens or a similar converging lens, may additionally be disposed either between the deviating mirror and the transmission or reception diode chip 1, i.e. for example inside the passage opening, or between the deviating mirror and the fiber connection opening.

One essential feature of the present invention is that the transmission or reception diode chip 1 immediately faces the passage opening 7. This is achieved, in the case of the illustrative embodiment in FIG. 1, by mounting the transmission or reception diode chip 1 on a submount 2. The submount 2 is in turn mounted on a support plate 5 which covers the passage opening 7 on the first main surface 4 and is fastened at both sides of the passage opening 7 on the first main surface 4. Production is carried out by mounting the submount 2 and the transmission or reception diode chip 1 on the support plate 5, and then fastening the support plate 5 of the first main surface 4 in such a way that the transmission or reception diode chip 1 protrudes into the passage opening 7. The result achieved by this is that a radiation beam emitted by the transmission diode chip 1, or a radiation beam striking the reception diode chip 1, does not need to pass through a transparent support material.

The submount 2 may be a mechanical support without any optoelectronic function, on which the transmission or reception diode chip 1 is mounted. Provision may, however, also be made for the submount 2 to form a reception diode, the upper surface of which forms a photosensitive surface. The reception diode may, for example, be a monitor diode for the semiconductor laser of the transmission diode chip 1. Provision may, however, also be made for an upper surface of the submount 2, lying outside the fitted transmission diode chip 1, to be configured as a light-reception surface, so that the submount 2 can be used in general as a reception diode for reception radiation. For this application case, the submount 2 is produced from a semiconductor material, such as silicon. The support plate 5 may be produced from any desired material; it is for example possible to use a ceramic material. The support plate 5 may have electrical through-contacts 6 in order to electrically contact the transmission and/or reception diode chips 1 and 2 at both sides of the support plate 5 by bonding wires.

In addition, further electronic or optoelectronic components, such as a preamplifier 12, may be disposed on the first main surface 4 of the mounting platform 9, and may be electrically connected to the transmission and/or reception diode chips 1 and 2 by bonding wires.

A second illustrative embodiment, represented in FIG. 2, employs the mounting platform 9 and is electrically insulating but is provided with electrical interconnections 9A on the first main surface 4. The mounting platform 9 in FIG. 2 moreover has two circular passage openings 7. The left-hand half of the image represents the way in which the support plate 5, with a fitted submount 2 and the transmission or reception diode chip 1, is mounted in the passage opening 7. At both sides of the passage opening 7, there are interconnections 9A on the first main surface 4. The right-hand half of the image in FIG. 2 represents the second aspect of the present invention by way of example. In this case, a reception diode chip 3 is put over the passage opening 7 on the first main surface 4 and is contacted with interconnections 9A at both sides of the passage opening 7.

The reception diode chip 3 may in this case additionally contain the integrated preamplifier. The photosensitive reception surface of the reception diode chip 3 therefore directly faces the passage opening 7, so that the incoming radiation beam does not need to pass initially through a transparent support.

The third illustrative embodiment of the optical transmission or reception unit according to the invention, represented in FIG. 3, is modified in two regards compared with the first illustrative embodiment represented in FIG. 1. The electrically insulating mounting platform 9 made of a plastic material, which has the structured interconnections 9A applied to the first main surface 4 and is used as in the second illustrative embodiment in FIG. 2, is used instead of the mounting platform 9 fabricated from a lead frame. The essential change from the first illustrative embodiment is, however, that the support plate 5 is omitted and, instead of it, use is made of the submount 2 which, in at least one direction, has an extent that is greater than the diameter of the passage opening 7, so that the passage opening 7 can be covered by the submount 2 at least in this direction on the first main surface 4. The submount 2 may again be a purely mechanical support, in which case it may be fabricated from any desired solid-state material. It may also, however, advantageously be produced from a semiconductor material, such as silicon, and fulfill an optoelectronic function such as a monitor diode for the transmission diode chip 1 mounted on it, or as a general reception diode—as described above.

A further advantage of the present invention is that, in the case of an optical transmission and/or reception unit, when a plurality of passage openings 7 are used and equipped, the transmission and reception diode chips fastened in them are shielded optimally from one another by the nature of the configuration.

The passage openings 7 need not, as in the illustrative embodiments shown, fully cover the passage openings 7 of the first main surface 4. Instead, it is sufficient if they partially cover them, so long as the optoelectronic transducers directly face the passage openings 7 and are held securely and firmly.

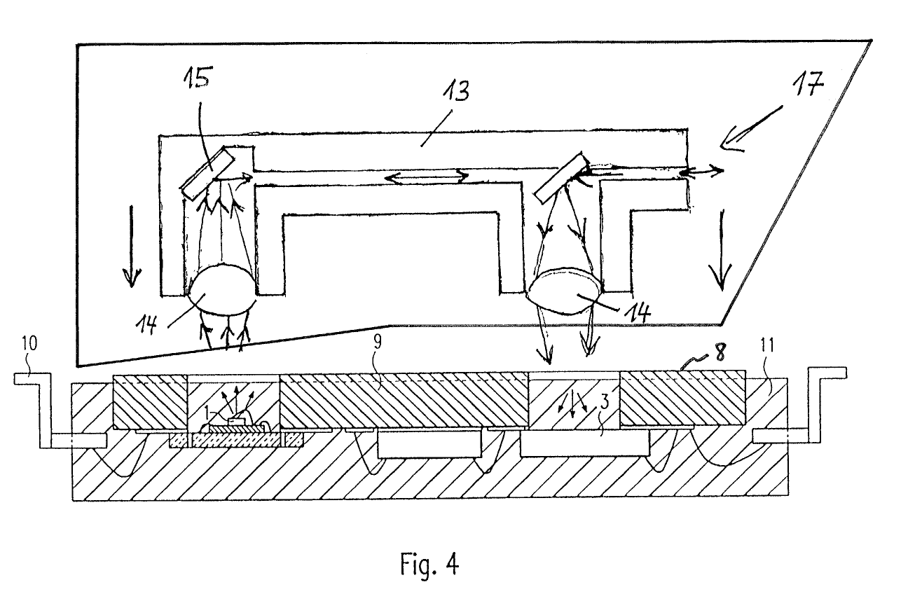

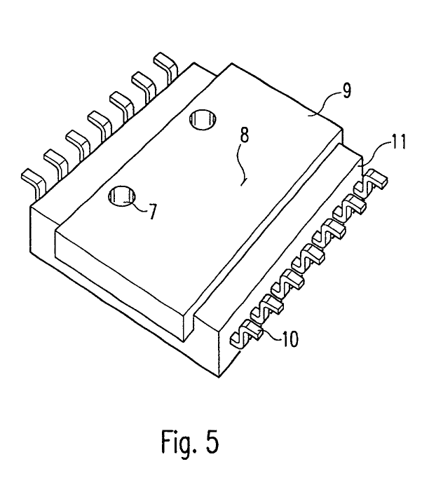

Lastly, FIG. 4 represents a development of the illustrative embodiment in FIG. 2 to form a surface-mountable transmission and reception component. A development of this type can also be seen in a perspective representation in FIG. 5. The development consists in surrounding the mounting platform 9, and the transmission and reception diode chips 1 and 3 linked to it, with a plastic encapsulation 11 in which suitable electrical connections 10 are made at the edge. The electrical connections 10 are formed in such a way that they have external end sections that lie in a common plane which is parallel with the main surfaces of the mounting platform 9. This plane may in this case be positioned on the light exit S side of the passage openings 7, as in the illustrative embodiment in FIG. 4, or may be positioned on the opposite side. In the former case, which is represented in FIG. 4, passage holes, through which the light of the transmission radiation and the reception radiation passes, are drilled in the board. In the latter case, an optical beam guiding device, such as a beam deviation receptacle, may be mounted on the board.

As is shown in FIG. 5, the plastic compound 11 encloses the mounting platform 9 in a box fashion, the second main surface of the mounting platform 9 not being covered with the plastic compound 11 and the passage openings 7 also not being filled with any plastic compound. At their respective end section inside the plastic compound 11, the electrical connections 10 are linked by bonding wires to corresponding end sections of the interconnections 9A on the first main surface 4 of the mounting platform 9. As indicated above, it is also possible to use a lead frame as the mounting platform 9, so that the bonding wires need to be linked to the corresponding conductive connection sections of the lead frame.

I claim:

1. An optical unit, comprising:
a mounting platform having a first main surface, a second main surface, and at least one passage opening formed therein and extending between said first main surface and said second main surfaces;
a support plate extending on a side of said first main surface and extending at least partially over said passage opening; and
a diode chip being at least one of a transmission and reception diode chip disposed on said support plate and fastened such that said diode chip immediately faces said passage opening.

2. The optical unit according to claim 1, wherein said diode chip is fastened directly on said first main surface of said support plate.

3. The optical unit according to claim 1, including a submount on which said diode chip is fastened, and said submount is fastened on said support plate.

4. The optical unit according to claim 3, wherein:
said submount is produced from a semiconductor material, including silicon;
said diode chip is a transmission diode chip fastened on said submount; and
said submount is a photodiode.

5. The optical unit according to claim 3, wherein said submount is produced from a semiconductor material, including silicon.

6. The optical unit according to claim 1, wherein said support plate is produced from a ceramic material.

7. The optical unit according to claim 1, including electrical interconnections for electronic contacting of said diode chip and disposed on said first main surface of said mounting platform.

8. The optical unit according to claim 1, wherein said mounting platform is produced from a lead frame.

9. An optical unit, comprising:
a mounting platform having a first main surface, a second main surface, and at least one passage opening formed therein and extending between said first main surface and said second main surface; and
a reception diode chip having a light-reception surface and extending on a side of said first main surface at least partially over said passage opening, so that said light-reception surface of said reception diode chip immediately faces said passage opening.

10. The optical unit according to claim 9, including a preamplifier integrated in said reception diode chip.

11. The optical unit according to claim 9, including electrical interconnections disposed on said first main surface of said mounting platform and connected to said reception diode chip.

12. The optical unit according to claim 9, wherein said mounting platform is produced from a lead frame.

13. An optical component, comprising:
an optical unit, including:
a mounting platform having a first main surface, a second main surface, electrical interconnections disposed on said first main surface, and at least one passage opening formed therein and extending between said first main surface and said second main surfaces;
a support plate extending on a side of said first main surface and extending at least partially over said passage opening; and
a diode chip being at least one of a transmission and reception diode chip disposed on said support plate and fastened such that said diode chip immediately faces said passage opening; and
electrical connections connected to said electrical interconnections of said mounting platform and said electrical connections being lead out in such a way that, in each case, said electrical connections have end sections lying in a common plane.

14. The optical component according to claim 13, including a plastic encapsulation at least partially surrounding said optical unit and said electrical connections, and said electrical connections extending out from said plastic encapsulation.

15. An optical component, comprising:
an optical unit, including:
a mounting platform having a first main surface, a second main surface, electrical interconnections disposed on said first main surface, and at least one passage opening formed therein and extending between said first main surface and said second main surfaces;
a support plate extending on a side of said first main surface and extending at least partially over said passage opening; and
a diode chip being at least one of a transmission and reception diode chip disposed on said support plate and fastened such that said diode chip immediately faces said passage opening; and
an optical device for beam guiding disposed on said second main surface of said mounting platform.

16. The optical component according to claim 15, wherein said optical device is a beam deviation receptacle with a deviating mirror and a connection opening for an optical fiber.

17. The optical unit according to claim 4, wherein said submount is a monitor diode for said transmitter diode chip.

18. An optical component, comprising:
an optical unit, including:
a mounting platform having a first main surface, a second main surface, electrical interconnections disposed on said first main surface, and at least one passage opening formed therein and extending between said first main surface and said second main surface; and
a reception diode chip having a light-reception surface and extending on a side of said first main surface at least partially over said passage opening, so that said light-reception surface of said reception diode chip immediately faces said passage opening; and
electrical connections connected to said electrical interconnections of said mounting platform and said electrical connections being lead out in such a way that, in each case, said electrical connections have end sections lying in a common plane.

19. The optical component according to claim 18, including a plastic encapsulation at least partially surrounding said optical unit and said electrical connections, and said electrical connections extending out from said plastic encapsulation.

20. An optical component, comprising:
an optical unit, including:
a mounting platform having a first main surface, a second main surface, electrical interconnections disposed on said first main surface, and at least one passage opening formed therein and extending between said first main surface and said second main surface; and
a reception diode chip having a light-reception surface and extending on a side of said first main surface at least partially over said passage opening, so that said light-reception surface of said reception diode chip immediately faces said passage opening; and
an optical device for beam guiding disposed on said second main surface of said mounting platform.

21. The optical component according to claim 20, wherein said optical device is a beam deviation receptacle with a deviating mirror and a connection opening for an optical fiber.
